(19) United States
(12) Patent Application Publication
(10) Pub. No.: US 2026/0123510 A1
(43) Pub. Date: Apr. 30, 2026

(54) SEMICONDUCTOR DEVICE AND SEMICONDUCTOR STRUCTURE

(71) Applicant: REALTEK SEMICONDUCTOR CORP., Hsinchu (TW)

(72) Inventors: Nai-Jen Hsuan, Hsinchu (TW); Wen-Cheng Yang, Hsinchu (TW)

(73) Assignee: REALTEK SEMICONDUCTOR CORP., Hsinchu (TW)

(21) Appl. No.: 19/330,901

(22) Filed: Sep. 17, 2025

Related U.S. Application Data
(60) Provisional application No. 63/711,325, filed on Oct. 24, 2024.

(30) Foreign Application Priority Data
Jan. 17, 2025 (TW) 114102178

(51) Int. Cl. H01L 23/00

(52) U.S. Cl. CPC H10W 72/90; H10W 72/59; H10W 72/923; H10W 72/942; H10W 72/952

(57) ABSTRACT

A semiconductor device includes a substrate, a circuit layer, a dielectric layer, a trace layer, a metal buffer layer, and a metal wire bonding pad. The circuit layer is on an upper surface of the substrate. The dielectric layer is on an upper surface of the circuit layer. The trace layer is on an upper surface of the circuit layer and in the dielectric layer. The metal buffer layer is on an upper surface of the trace layer and in the dielectric layer. The metal wire bonding pad is on an upper surface of the metal buffer layer.

### CROSS-REFERENCE TO RELATED APPLICATION

This application claims the benefit of US provisional application serial No. 63/711,325, filed on October 24, 2024 and claims the priority of Patent Application No. 114102178 filed in Taiwan, R.O.C. on January 17, 2025. The entirety of the above-mentioned patent applications are hereby incorporated by references herein and made a part of the specification.

### BACKGROUND

### Technical Field

The instant disclosure relates to a design for preventing cracking of metal wire bonding pads, in particular to a semiconductor device and a semiconductor structure having a metal buffer layer.

### Related Art

With the advancement of semiconductor process technology, electronic products are trending toward being thin and lightweight, leading to increasingly requirements for semiconductor packaging. Currently, as known to the inventor, the common packaging architectures in the semiconductor industry primarily adopt a single-layer metal (one metal) process and wire-bonding packaging technology.

### SUMMARY

In packaging architectures that adopt the single-layer metal and wire-bonding process, the single-layer metal (e.g., aluminum) used for wire bonding is prone to cracking or deformation because of the wire-bonding process. In particular, when a device operates under a high-temperature environment or for a prolonged duration, the material of the single-layer metal (e.g., aluminum) is susceptible to structural damages due to thermal stress and mechanical stress induced by wire bonding. Such cracking or deformation not only affects the electrical conductivity and stability of the device but may also lead to the failure of the entire packaging structure.

In some embodiments, a semiconductor device comprises a substrate, a circuit layer, a dielectric layer, a trace layer, a metal buffer layer, and a metal wire bonding pad. The circuit layer is on an upper surface of the substrate. The dielectric layer is on an upper surface of the circuit layer. The trace layer is on an upper surface of the circuit layer and in the dielectric layer. The metal buffer layer is on an upper surface of the trace layer and in the dielectric layer. The metal wire bonding pad is on an upper surface of the metal buffer layer.

In some embodiments, the trace layer comprises a plurality of vertical traces, and the metal buffer layer is connected to the circuit layer through the vertical traces.

In some embodiments, each of the vertical traces is connected to an input terminal or an output terminal of the circuit layer.

In some embodiments, the trace layer further comprises a plurality of horizontal traces.

In some embodiments, at least one of the horizontal traces passes between two adjacent vertical traces among the vertical traces.

In some embodiments, at least one of the horizontal traces is connected to a power terminal of the circuit layer.

In some embodiments, at least one of the horizontal traces is connected to a ground terminal of the circuit layer.

In some embodiments, the semiconductor device further comprises a passivation layer. The passivation layer is formed on the dielectric layer and has an opening corresponding to the metal wire bonding pad.

In some embodiments, the metal wire bonding pad is made of aluminum.

In some embodiments, a size of the metal buffer layer is the same as a size of the metal wire bonding pad.

In some embodiments, a semiconductor structure comprises the semiconductor device according to any of the foregoing embodiments and a plurality of wires. The wires are wire-bonded to the metal wire bonding pad of the semiconductor device.

In some embodiments, the wires are wire-bonded to a central region of a region of the metal wire bonding pad corresponding to the opening.

In some embodiments, the region of the metal wire bonding pad corresponding to the opening comprises a plurality of corner regions, and the wires are wire-bonded to the corner regions evenly.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The disclosure will become more fully understood from the detailed description given herein below for illustration only, and thus not limitative of the disclosure, wherein:

FIG. 1 illustrates a cross-sectional schematic view of a semiconductor device according to an embodiment;

FIG. 2 illustrates a top view of a trace layer according to an embodiment;

FIG. 3 illustrates a cross-sectional schematic view of a semiconductor structure according to an embodiment;

FIG. 4A illustrates a schematic view of a region of a metal wire bonding pad corresponding to an opening according to an embodiment; and

FIG. 4B illustrates a schematic view of a region of a metal wire bonding pad corresponding to an opening according to another embodiment.

### DETAILED DESCRIPTION OF THE INVENTION

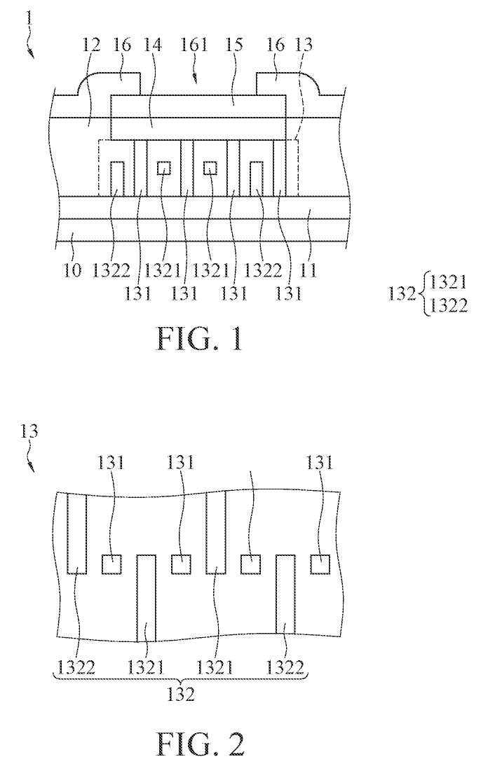

FIG. 1 illustrates a cross-sectional schematic view of a semiconductor device 1 according to an embodiment. Please refer to FIG. 1. The semiconductor device 1 comprises a substrate 10, a circuit layer 11, a dielectric layer 12, a trace layer 13, a metal buffer layer 14, and a metal wire bonding pad 15. The circuit layer 11 is on an upper surface of the substrate 10. The dielectric layer 12 is on an upper surface of the circuit layer 11. The trace layer 13 is on an upper surface of the circuit layer 11 and in the dielectric layer 12. The metal buffer layer 14 is on an upper surface of the trace layer 13 and in the dielectric layer 12. The metal wire bonding pad 15 is on an upper surface of the metal buffer layer 14.

In some embodiments, the metal buffer layer 14 may be but not limited to a via.

In some embodiments, the metal wire bonding pad 15 may be made of but not limited to aluminum. In some embodiments, the metal buffer layer 14 may be made of but not limited to copper.

In some embodiments, the metal buffer layer 14 can provide additional support to the metal wire bonding pad 15, thereby reducing the stress applied on the metal wire bonding pad 15. Specifically, in some embodiments, since the metal buffer layer 14 is on a lower surface of the metal wire bonding pad 15, the metal buffer layer 14 provides a larger support area for the metal wire bonding pad 15, allowing the mechanical stress induced by wire bonding to be more evenly dispersed within the structure formed by the metal buffer layer 14 and the metal wire bonding pad 15. Therefore, mechanical stress can be prevented from concentrating on the metal wire bonding pad 15. Hence, the dispersion of mechanical stress within the structure formed by the metal buffer layer 14 and the metal wire bonding pad 15 can be improved. Additionally, the metal buffer layer 14 can enhance the support strength of the structure formed by the metal buffer layer 14 and the metal wire bonding pad 15, therefore the likelihood of deformation and displacement of the metal wire bonding pad 15 can be reduced, thereby improving the stability of the structure. Furthermore, the metal buffer layer 14 provides a better heat dissipation path for the metal wire bonding pad 15, reducing the formation of localized hotspots on the metal wire bonding pad 15 and mitigating the stress generated on the metal wire bonding pad 15 due to thermal expansion and contraction. As a result, the thermal stress applied on the metal wire bonding pad 15 is alleviated. That is, in some embodiments, the semiconductor device 1, due to the presence of the metal buffer layer 14, exhibits improved structural integrity, higher reliability, and a longer operational lifespan.

In some embodiments, a size of the metal buffer layer 14 is the same as a size of the metal wire bonding pad 15, but the instant disclosure is not limited thereto. In some embodiments, the size of the metal buffer layer 14 is greater than the size of the metal wire bonding pad 15.

In the case that the size of the metal buffer layer 14 is the same as or greater than the size of the metal wire bonding pad 15, the contact area between the metal buffer layer 14 and the metal wire bonding pad 15 increases. This larger contact area reduces the contact resistance between the metal buffer layer 14 and the metal wire bonding pad 15, while also increasing the cross-sectional area for current flow, thereby reducing the overall resistance of the semiconductor device 1. Additionally, the metal buffer layer 14, which has a larger contact area with the metal wire bonding pad 15, provides a broader and more uniform conductive path, preventing current concentration in small regions that could lead to hotspots. Therefore, the issue of excessively high local current density is mitigated. As a result, electromagnetic interference and thermal effects caused by high current density of the semiconductor device 1 are reduced, and the electromagnetic compatibility (EMC) of the semiconductor device 1 is improved. That is, in some embodiments, the semiconductor device 1, due to the presence of the metal buffer layer 14, exhibits better electrical performance, lower operating temperature, and reduced IREM (Internal Resistance and Electromagnetic effects).

Since the metal buffer layer 14 provides sufficient mechanical support and stress dispersion, the trace layer 13 can be safely disposed on the bottom portion of the metal buffer layer 14 without the risk of being crushed or affected by the cracking or deformation of the metal wire bonding pad 15. As mentioned above, when external forces (such as the stress during the wire bonding process) is applied on the metal wire bonding pad 15, the stress is first uniformly absorbed and dispersed by the metal buffer layer 14, thereby reducing the stress transmitted to the trace layer 13. Therefore, the trace layer 13 can be effectively prevented from being damaged or crushed by the external forces.

In the packaging architectures art known to the inventor, due to the lack of a supporting structure such as the metal buffer layer 14, the metal wire bonding pad of the packaging architectures known to the inventor was prone to cracking or deformation under the mechanical stress during the wire bonding process, which could then crush the trace layer beneath the metal wire bonding pad. As a result, in the packaging architectures art known to the inventor, the trace layer could not be disposed beneath the metal wire bonding pad, severely limiting the flexibility and reliability of structural design of the packaging architectures known to the inventor. However, according to one or some embodiments of the instant disclosure, such drawback can be overcome by providing the metal buffer layer 14 beneath the metal wire bonding pad 15, which effectively offers support and stress dispersion. Therefore, the trace layer 13 is allowed to be safely disposed beneath the metal buffer layer 14, thereby successfully addressing the shortcomings of the packaging architectures art known to the inventor where the trace layer could not be disposed.

Since the trace layer 13 can be safely disposed beneath the metal buffer layer 14, the semiconductor device 1 has more wiring space and conductive path options in both the vertical and horizontal directions, thereby increasing the wiring flexibility of the semiconductor device 1. In some embodiments, the trace layer 13 comprises a plurality of vertical traces 131. The metal buffer layer 14 is connected to the circuit layer 11 through the vertical traces 131. In some embodiments, each of the vertical traces 131 is connected to an input terminal or an output terminal of the circuit layer 11.

In some embodiments, the trace layer 13 further comprises a plurality of horizontal traces 132. In FIG. 1, the horizontal traces 132 comprise a plurality of horizontal traces 1321 and a plurality of horizontal traces 1322. The horizontal traces 1321 are not directly connected to the circuit layer 11 shown in FIG. 1, but instead are connected to the circuit layer 11 of the semiconductor device 1, which is not shown in this cross-sectional view (FIG. 1). In other words, in some embodiments, the horizontal traces 1321 are merely horizontal traces 132 passing through the cross-section of the semiconductor device 1 shown in FIG. 1. In contrast, the horizontal traces 1322 are horizontal traces 132 directly connected to the circuit layer 11 of the cross-section of the semiconductor device 1 shown in FIG. 1.

In some embodiments, at least one of the horizontal traces 132 is connected to a power terminal of the circuit layer 11. In some embodiments, at least one of the horizontal traces 132 is connected to a ground terminal of the circuit layer 11. In some embodiments, when the horizontal traces 1321 are connected to the power terminal of the circuit layer 11, the horizontal traces 1322 are connected to the ground terminal of the circuit layer 11. In some embodiments, when the horizontal traces 1321 are connected to the ground terminal of the circuit layer 11, the horizontal traces 1322 are connected to the power terminal of the circuit layer 11. That is, in some embodiments, the horizontal traces 1321 and the horizontal traces 1322 are connected to different terminals of the circuit layer 11.

FIG. 2 illustrates a top view of a trace layer 13 according an embodiment. The trace layer 13 in FIG. 2 corresponds to the trace layer 13 in FIG. 1. Please refer to FIG. 1 and FIG. 2. In some embodiments, at least one of the horizontal traces 132 passes between two adjacent vertical traces 131 among the vertical traces 131. In some embodiments, the horizontal traces 1321 are connected to the same terminal of the circuit layer 11 and thus extend horizontally in the same direction. In some embodiments, the horizontal traces 1322 are connected to the same terminal of the circuit layer 11 and thus extend horizontally in the same direction. In some embodiments, since the traces 1321 and the horizontal traces 1322 are connected to different terminals of the circuit layer 11, the horizontal traces 1321 and the horizontal traces 1322 extend horizontally in different directions.

Through the configuration of the trace layer 13, the semiconductor device 1 achieves greater wiring flexibility. By utilizing the vertical traces 131 and the horizontal traces 132, the semiconductor device 1 can enable both vertical and horizontal signal transmission within the same region, thereby facilitating multi-path signal transmission. Therefore, the routing complexity of the semiconductor device 1 can be reduced and wiring congestion issues in high-density circuits can be addressed. Additionally, the vertical traces 131 and horizontal traces 132 allow for the shortest possible signal transmission paths, minimizing additional parasitic capacitance and resistance in signal transmission. Shorter signal transmission paths result in reduced time delays, and since delay is a major performance bottleneck in high-speed circuits, reducing delay directly enhances the circuit’s response speed, enabling the semiconductor device 1 to support higher-frequency signal transmission. In other words, in some embodiments, the semiconductor device 1 exhibits improved design flexibility and superior electrical performance due to the configuration of the trace layer 13.

In some embodiments, the semiconductor device 1 further comprises a passivation layer 16. The passivation layer 16 is formed on the dielectric layer 12 and has an opening 161. The opening 161 corresponds to the metal wire bonding pad 15.

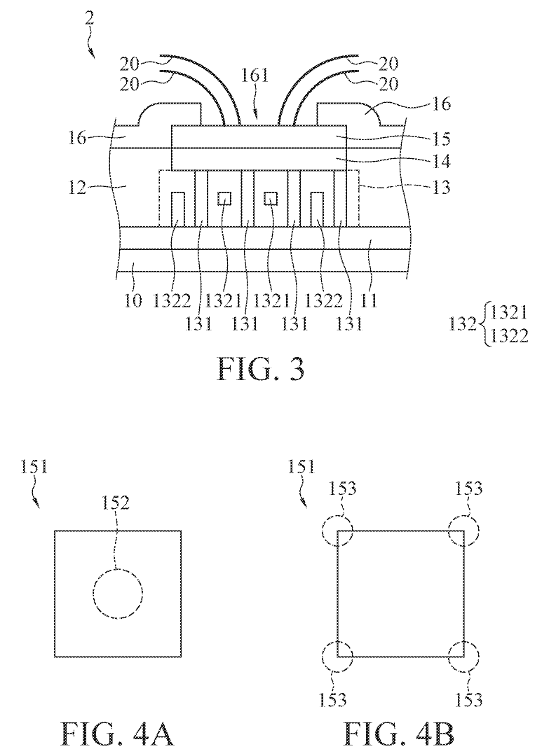

FIG. 3 illustrates a cross-sectional schematic view of a semiconductor structure 2 according to an embodiment. Please refer to FIG. 3. The semiconductor structure 2 comprises the semiconductor device 1 shown in FIG. 1 and a plurality of wires 20. The wires 20 are wire-bonded to the metal wire bonding pad 15.

FIG. 4A illustrates a schematic view of a region 151 of the metal wire bonding pad 15 corresponding to the opening 161 according to an embodiment. Please refer to FIG. 3 and FIG. 4A. In some embodiments, the wires 20 are wire-bonded to a central region 152 of the region 151 of the metal wire bonding pad 15 corresponding to the opening 161. In FIG. 4A, the stress generated by the wire bonding of the wires 20 is applied to the metal wire bonding pad 15 in a single-point manner. In other words, in this embodiment, the stress generated by the wire bonding of the wires 20 is concentrated at a single point which may generate greater stress on the metal wire bonding pad 15, thereby increasing the risk of cracking or deformation of the metal wire bonding pad 15.

FIG. 4B illustrates a schematic view of the region 151 of the metal wire bonding pad 15 corresponding to the opening 161 according to another embodiment. Please refer to FIG. 3 and FIG. 4B. In some embodiments, the region 151 of the metal wire bonding pad 15 corresponding to the opening 161 comprises a plurality of corner regions 153. In some embodiments, the wires 20 are wire-bonded to the corner regions 153 evenly. In FIG. 4B, the stress generated by the wire bonding of the wires 20 is applied to the metal wire bonding pad 15 in a multi-point manner. In other words, in this embodiment, the stress generated by the wire bonding of the wires 20 is dispersed across multiple points which reduces the pressure intensity at each of the corner regions 153, thereby reducing the risk of cracking or deformation of the metal wire bonding pad 15. That is, in some embodiments, the semiconductor structure 2 improves the reliability and durability of the metal wire bonding pad 15 by wire-bonding the wires 20 to the corner regions 153 evenly.

To sum up, in some embodiments, the semiconductor device 1 exhibits improved structural integrity, higher reliability, longer lifespan, better electrical performance, lower operating temperature, and reduced IREM due to the configuration of the metal buffer layer 14. Additionally, in some embodiments, the semiconductor device 1 achieves enhanced design flexibility and superior electrical performance due to the configuration of the trace layer 13.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A semiconductor device comprising:
a substrate;
a circuit layer on an upper surface of the substrate;
a dielectric layer on an upper surface of the circuit layer;
a trace layer on an upper surface of the circuit layer and in the dielectric layer;
a metal buffer layer on an upper surface of the trace layer and in the dielectric layer; and
a metal wire bonding pad on an upper surface of the metal buffer layer.

2. The semiconductor device according to claim 1, wherein the trace layer comprises a plurality of vertical traces, and the metal buffer layer is connected to the circuit layer through the vertical traces.

3. The semiconductor device according to claim 2, wherein each of the vertical traces is connected to an input terminal or an output terminal of the circuit layer.

4. The semiconductor device according to claim 2, wherein the trace layer further comprises a plurality of horizontal traces.

5. The semiconductor device according to claim 4, wherein at least one of the horizontal traces passes between two adjacent vertical traces among the vertical traces.

6. The semiconductor device according to claim 4, wherein at least one of the horizontal traces is connected to a power terminal of the circuit layer.

7. The semiconductor device according to claim 4, wherein at least one of the horizontal traces is connected to a ground terminal of the circuit layer.

8. The semiconductor device according to claim 1, further comprising a passivation layer formed on the dielectric layer, wherein the passivation layer has an opening corresponding to the metal wire bonding pad.

9. The semiconductor device according to claim 1, wherein the metal wire bonding pad is made of aluminum.

10. The semiconductor device according to claim 1, wherein a size of the metal buffer layer is the same as a size of the metal wire bonding pad.

11. A semiconductor structure comprising:
the semiconductor device according to claim 8; and
a plurality of wires wire-bonded to the metal wire bonding pad of the semiconductor device.

12. The semiconductor structure according to claim 11, wherein the wires are wire-bonded to a central region of a region of the metal wire bonding pad corresponding to the opening.

13. The semiconductor structure according to claim 11, wherein the region of the metal wire bonding pad corresponding to the opening comprises a plurality of corner regions, and the wires are wire-bonded to the corner regions evenly.
